(19) United States
(12) Patent Application Publication
(10) Pub. No.: US 2003/0008493 A1
(43) Pub. Date: Jan. 9, 2003

(54) Interconnect structure manufacturing

(76) Inventor: Shyh-Dar Lee, Hsinchu Hsien (TW)

Correspondence Address: BIRCH STEWART KOLASCH & BIRCH, PO BOX 747, FALLS CHURCH, VA, 22040-0747, US

(21) Appl. No.: 09/897,637

(22) Filed: Jul. 3, 2001

(51) Int. Cl. H01L 21/4763

(52) U.S. Cl. 438/626; 438/629

(57) ABSTRACT

A method to fabricate an interconnect structure is provided. First, an inter-metal dielectric layer is formed on a substrate. Then the inter-metal dielectric layer is etched to form a trench, and a barrier layer is formed on the trench. Afterwards, a metal layer is formed to fill the trench over the barrier layer. Then chemical mechanical polishing (CMP) is performed to remove the barrier layer and the metal layer on the inter-metal dielectric layer. Next, an adhesion layer is formed to cover the metal layer and the inter-metal dielectric layer. Finally, a sealing layer is formed to cover the adhesion layer.

### BACKGROUND OF THE INVENTION

1. Field of the Invention

The present invention relates in general to a process for manufacturing an interconnect structure. In particular, the present invention relates to advance formation of an adhesion layer having superior adhesion characteristics on a metal layer, then formation of a sealing layer for anti-diffusion of ions of the metal layer. Therefore, the adhesion between the sealing layer and the metal layer of the interconnect structure will be improved to avoid the problems of electro-migration.

2. Description of the Related Art

In ultra large-scale integrated (ULSI) circuit manufacturing, semiconductor devices are fabricated on a substrate or a silicon wafer. After the formation of the devices, metal lines for interconnection are defined using a metallization. As the integration of integrated circuits increases, manufacturing with high yield and highly reliable metal interconnect lines is hard to achieve. A method of fabricating a metal-damascene structure is to etch trenches for metal interconnect lines and then fill the trenches with metal material. In addition, chemical mechanical polishing (“CMP” hereinafter) is used to polish the metal material. The method offers a better way to fabricate a submicron VLSI interconnection with high performance and high reliability.

In the following description, a conventional method for fabricating a damascene structure on a substrate is explained with reference to FIGS. 1A to 1D.

First, referring to FIG. 1A, a substrate 100 is provided and a metal interconnect line 110 is fabricated in the substrate 100. Next, a sealing layer 120 is formed covering the metal interconnect line 110. Then, an inter-metal dielectric (IMD) layer 120 is formed covering the sealing layer 120. The sealing layer 120 can be silicon nitride (SiN) or silicon carbide (SiC) The sealing layer 120 is provided for sealing the metal interconnect line 110 and for avoiding the ions of the metal interconnect line 110 diffusing to other parts of the semiconductor device, causing a short circuit of the semiconductor device. Next, referring to FIG. 1B, the IMD layer 130 is defined by the damascene to form a dual damascene structure 140 extending through the IMD layer 130 and the sealing layer 120 to the metal interconnect line 110.

Then, referring to FIG. 1C, a barrier layer 150 is formed on the sidewalls and the bottom of the dual damascene structure 140 and the IMD layer 130 by CVD or PVD. Afterwards, a metal layer 160 is formed on the dual damascene structure 140 on the barrier layer 150. Finally, referring to FIG. 1D, CMP is performed to remove the metal layer 160 and the barrier layer 150 on the IMD layer 130 outside the dual damascene structure 140.

However, the requirement of adhesion between the copper metal layer and the sealing layer and the requirement of diffusion of the copper from the metal layer to the IMD layer are different. Therefore, a single sealing cannot meet the above requirements. For example, if the conventional sealing layer is SiN or SiC, but the conventional sealing layer is unable to adhere to the metal layer efficiently. Hence, electro-migration of the metal layer is generated, degrading the reliability of the semiconductor device.

Moreover, while CMP is performed, some metal oxide will be generated on the surface of the metal line 160. For example, if the metal is copper, the copper oxidizes, producing copper oxide (Cu₂O). The oxide will increase the resistance of the metal line and cause the surface of the metal layer to bulge. Thus, adhesion between the sealing layer and the metal line will be decreased. Furthermore, the increased resistance of the metal line will generate more heat during operation of the semiconductor device. Moreover, when the adhesion between the sealing layer and the metal line deteriorates, the electro migration of the metal line will be degraded, which will negatively influence the performance of the semiconductor device.

### SUMMARY OF THE INVENTION

The object of the present invention is to provide a method for interconnect structure manufacture, which can satisfy both the requirement for adhesion between the copper metal layer and the sealing layer and that for the diffusion of the copper from the metal layer to the IMD layer. The method of the present invention forms an adhesion layer, which adheres to the metal layer efficiently. The adhesion layer maybe silicon oxynitride (SiON), silicon containing oxygen, nitrogen and hydrogen (SiONH), silicon containing nitrogen and hydrogen (SiNH), silicon containing carbon and nitrogen (SICN) or silicon containing carbon and hydrogen (SiCH). The method according to the present invention then forms a sealing layer on the adhesion layer, which allows the sealing layer to avoid metal ions diffusing from the metal layer. The sealing layer maybe silicon nitride (SiN) or silicon carbide (SiC).

To achieve the above-mentioned object, the present invention provides a method to fabricate an interconnect structure, comprising the following steps.

First, an inter-metal dielectric layer is formed on a substrate. Then the inter-metal dielectric layer is etched to form a trench. A barrier layer is formed on the trench. Afterwards, a metal layer is formed to fill the trench over the barrier layer. Then chemical mechanical polishing (CMP) is performed to remove the barrier layer and the metal layer on the inter-metal dielectric layer. After the CMP, an adhesion layer is formed on the metal layer. Finally, a sealing layer is formed to cover the adhesion layer.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A-1D are section views illustrating a conventional method of manufacturing an interconnect structure.

FIGS. 2A-2J are section views illustrating a method of manufacturing an interconnect structure according to the embodiment of the present invention.

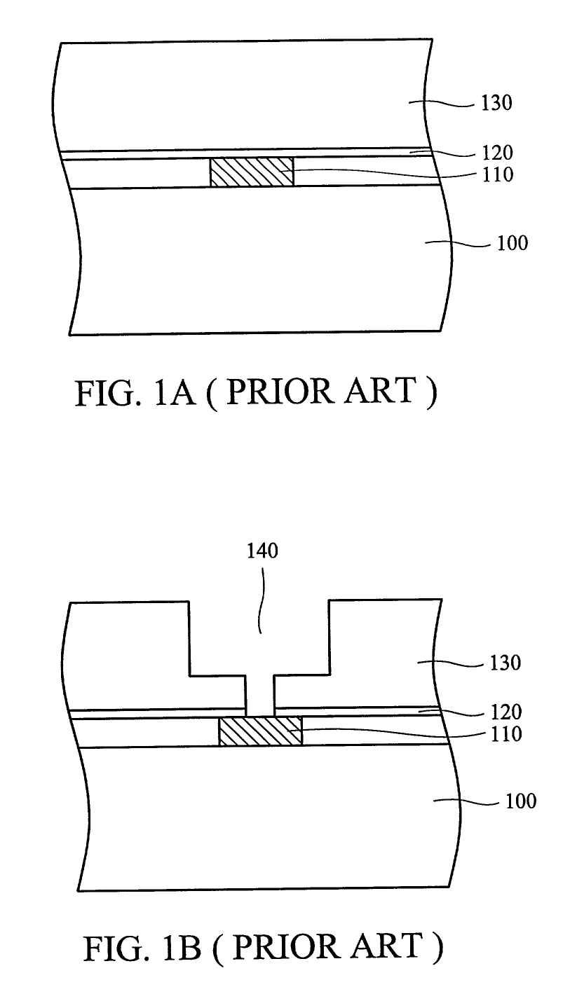

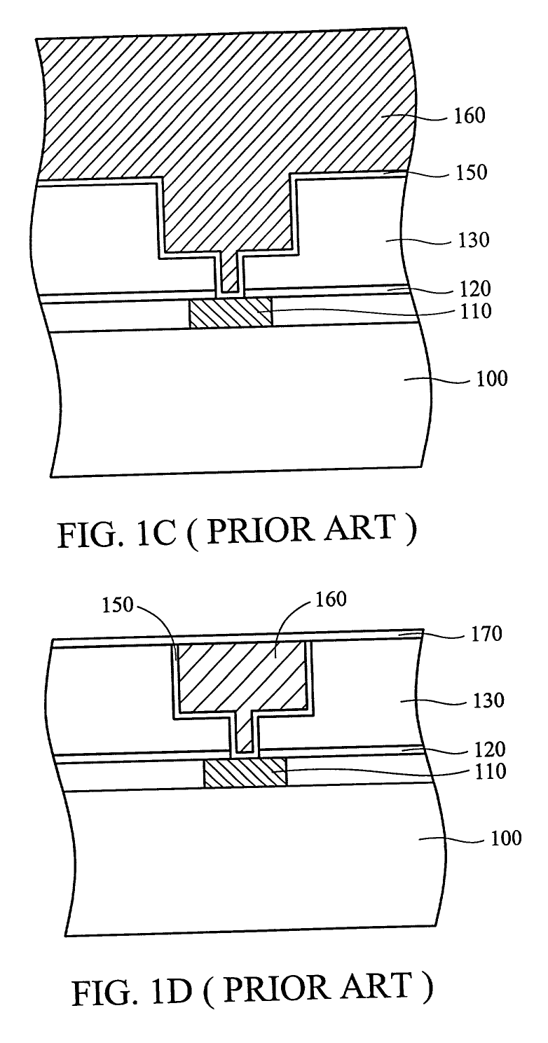

### DETAILED DESCRIPTION OF THE PREFERRED EMBODIMENT

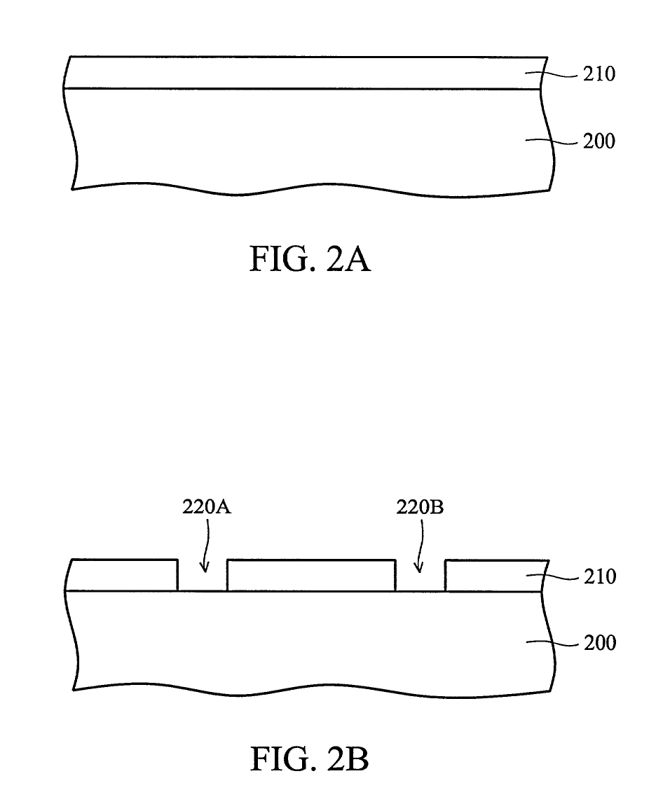

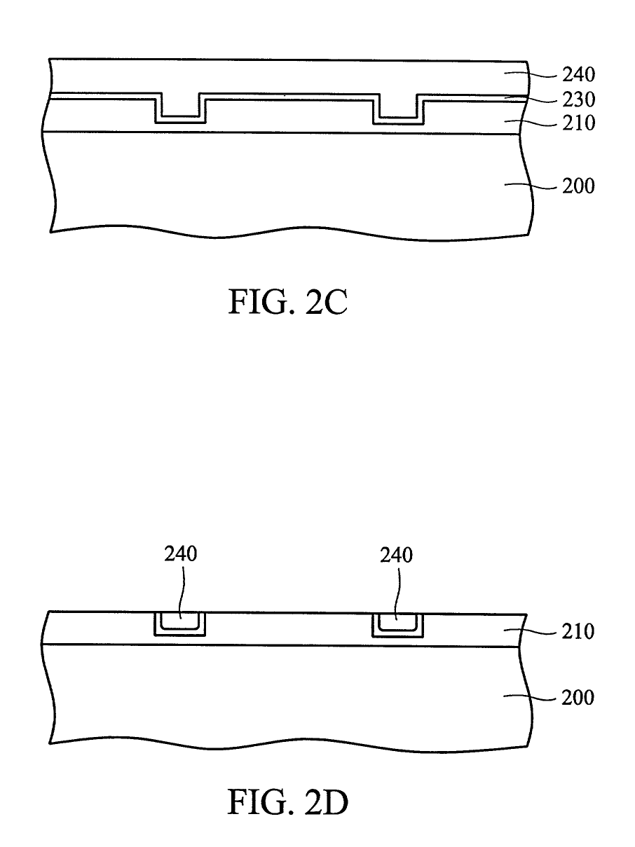

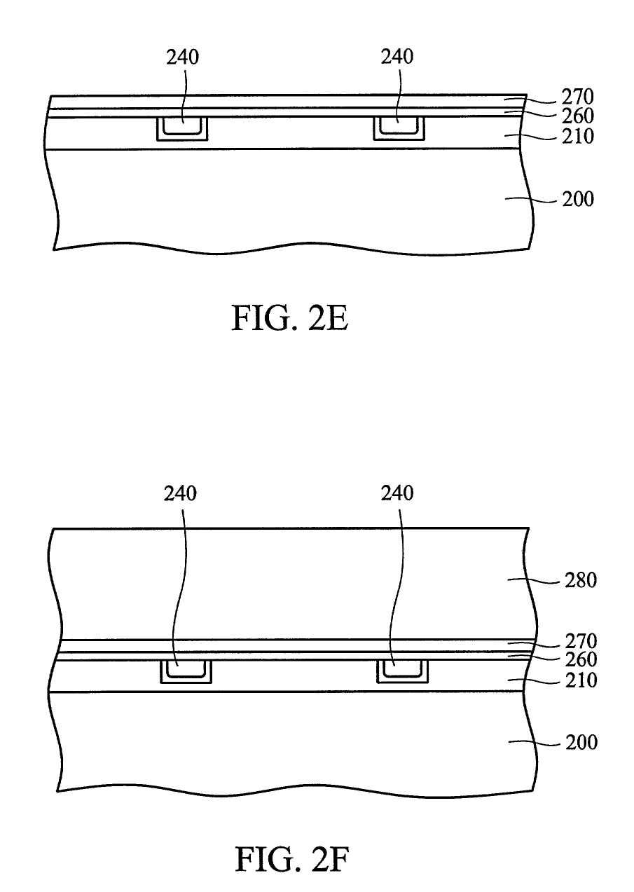

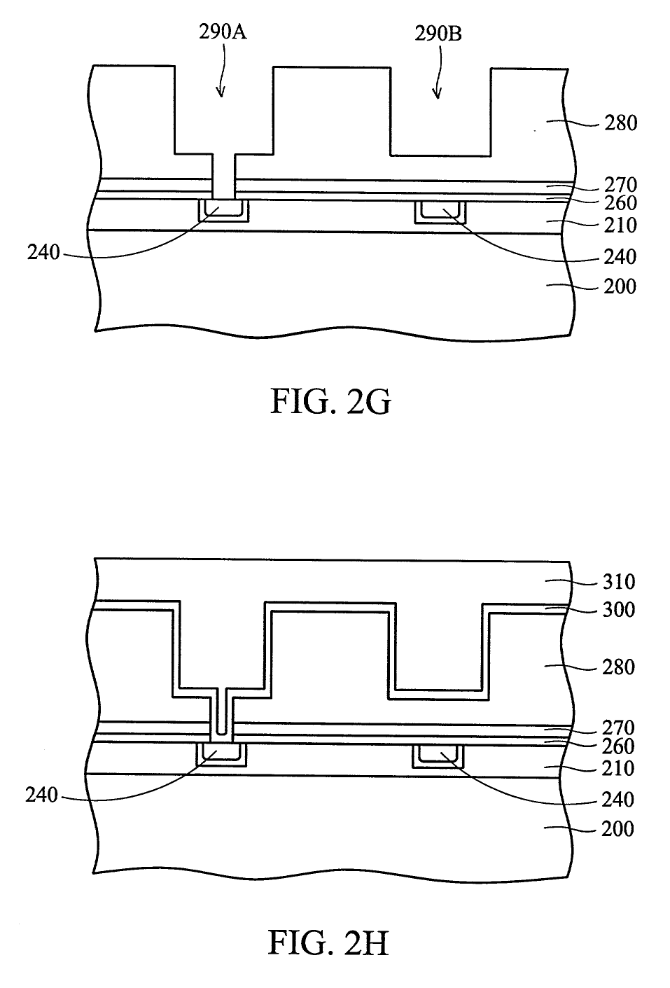

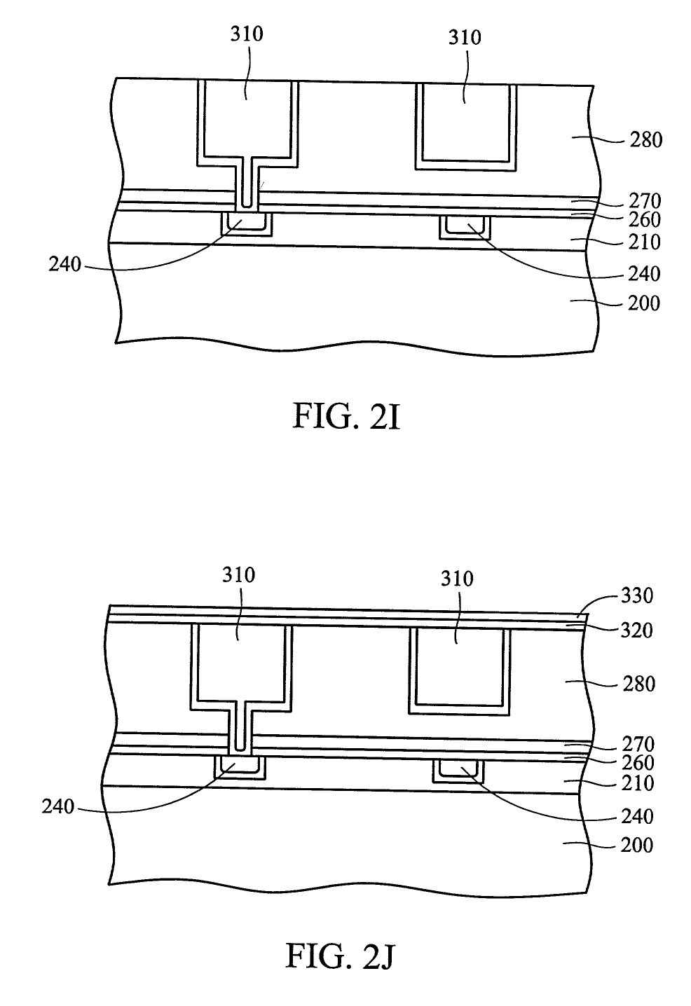

A method of fabricating a dual damascene structure on a substrate is described herein with reference to FIGS. 2A to 2J.

First, referring to FIG. 2A, a substrate 200 is provided for the present embodiment. Then, an inter-metal dielectric (IMD) layer 210 is formed on the substrate. The inter-metal dielectric layer 210 is composed of single layer or multi-layer low k dielectric material, wherein the k is dielectric constant. Next, referring to FIG. 2B, the inter-metal dielectric layer 210 is etched by lithography to form the trenches 220A and 220B. In the present embodiment, the trenches 220A and 220B are formed by anisotropic etching, and the depths of the trenches 220A and 220B are between about 2000 to 6000 angstroms.

Referring to FIG. 2C, a barrier layer 230 is formed on the sidewalls and the bottom of the trenches 220A and 220B. Then the metal layer 240 is disposed on the trench 220A and 220B on the barrier layer 230. The metal layer 240 may be copper, aluminum, tungsten, or others. In this embodiment, the metal layer 240 is a copper layer.

Referring to FIG. 2D, CMP is performed to remove the metal layer 240 and the barrier layer 230 from the inter-metal dielectric layer 210. However, during CMP and after, the copper oxide (Cu₂O) is generated on the remained metal layer 240 in the trenches 220A and 220B because of wetness. Moreover, the copper oxide (Cu₂O) will cause the surface of the metal layer to bulge. Therefore, the adhesion between the sealing layer 260, which is formed later, and the metal layer 240 is deteriorated. Hence, the reliability of the semiconductor is decreased.

A reduction is performed to solve this problem. The reduction provides a reduction gas to the surface of the metal layer 240. Therefore, the Cu₂O is reduced to Cu by free radicals. In the present invention, the reduction gas may be ammonia (NH₃), hydrogen (H₂), or silane (SiH₄). Alternately, the reduction gas may be a mixture of ammonia (NH3) and hydrogen (H2), or a mixture of silane (SiH4) and hydrogen (H2). Preferably, the silane is used as the reduction gas. The reduction is under the following conditions: flow rate of the reduction is between about 20 to 400 sccm; the pressure of the reduction is between about 0.01 to 10 torr; and the temperature of the reduction is between about 180 to 620° C. Therefore, the metal oxide is removed and the surface of the metal layer is planarized.

Afterwards, referring to FIG. 2E, an adhesion layer 260 is formed covering the metal layer 240 and the inter-metal dielectric layer 210 by plasma enhancement chemical vapor deposition (PECVD). The adhesion layer 260 may be silicon oxynitride (SiON), silicon containing oxygen, nitrogenand hydrogen (SiONH), silicon containing nitrogen and hydrogen (SiNH), silicon containing carbon and nitrogen (SiCN) or silicon containing carbon and hydrogen (SiCH), and the thickness of the adhesion layer 260 is between about 200 to 500 angstroms.

Next, a sealing layer 270 is formed covering on the surface of the adhesion layer 260. The sealing layer 270 may be silicon nitride (SiN) or silicon carbide (SiC), and the thickness of the sealing layer 270 is between about 200 to 850 angstroms.

In the present invention, the reliability of the semiconductor device will be improved by providing the adhesion layer 260 and the sealing layer 270, since the characteristics of the molecular structures of the sealing layer 270 and the adhesion layer 260 are different. As mentioned above, the adhesion layer 260 is silicon oxynitride (SiON), silicon containing oxygen, nitrogenand hydrogen (SiONH), silicon containing nitrogen and hydrogen (SiNH), silicon containing carbon and nitrogen (SICN) or silicon containing carbon and hydrogen (SiCH). Therefore, the molecular structures of the adhesion layer 260 containing such material have the necessary oxygen, hydrogen or nitrogen elements to combine with copper atoms. For this reason, a firmed structure such as Si—O—Cu forms at the interface between the adhesion layer 260 and the metal layer 240. Therefore, the adhesion between the adhesion layer 260 and the metal layer 240 is improved. In addition, the chemical characteristic of the sealing layer 270 is very stable. While the sealing layer 270 is formed on the adhesion layer 260, it is effective to avoid the copper ions diffusing to the inter-metal dielectric layer 280, which is formed in the following steps, by providing the sealing layer 270.

Referring to FIG. 2F, an inter-metal dielectric layer 280 is formed on the conductive sealing layer 270, wherein the inter-metal dielectric layer 280 is composed of single layer or multi-layer low k dielectric materials.

Next, referring to the FIG. 2G, the IMD layer 280 is defined by the damascene to form a trench 290B and a dual damascene structure 290A extending through the IMD layer 280, the adhesion layer 260 and the sealing layer 270 to the metal layer 240.

Then, referring to FIG. 2H, a barrier layer 300 is formed on the IMD layer 280 and the sidewalls and the bottom of the dual damascene structure 290A and the trench 290B by CVD or PVD. Afterwards, a metal layer 310 is formed on the dual damascene structure 290A and the trench 290B on the barrier layer 300. The metal layer 310 may be copper, aluminum, or tungsten, etc. In this present embodiment, the metal layer 310 is a copper layer.

Afterwards, referring to FIG. 2I, after the metal layer 310 is formed, CMP is performed to remove the metal layer 310 and the barrier layer 300 on the IMD layer 280. As mentioned above, during CMP and after, copper oxide (Cu₂O) is generated on the remaining metal layer 310.

Thus, a reduction is performed. The reduction provides a reduction gas to the surface of the metal layer 310. Therefore, the Cu₂O is reduced to Cu by free radicals. In the present invention, the reduction gas may be ammonia (NH₃), hydrogen (H₂), or silane (SiH₄). Alternately, the reduction gas may be a mixture of ammonia (NH3) or hydrogen (H₂), or a mixture of silane (SiH₄) and hydrogen (H₂). Preferably, the reduction gas is silane (SiH₄). The reduction is under the following conditions: flow rate of the reduction is between about 20 to 400 sccm; the pressure of the reduction is between about 0.01 to 10 torr; and the temperature of the reduction is between about 180 to 620° C.

Afterwards, referring to FIG. 2J, an adhesion layer 320 is formed covering the metal layer 310 and the inter-metal dielectric layer 280 by plasma enhancement chemical vapor deposition (PECVD). The adhesion layer 320 may be silicon oxynitride (SiON), silicon containing oxygen, nitrogenand hydrogen (SiONH), silicon containing nitrogen and hydrogen (SiNH), silicon containing carbon and nitrogen (SiCN) or silicon containing carbon and hydrogen (SiCH), and the thickness of the adhesion layer 260 is between about 200 to 500 angstroms.

Next, a sealing layer 330 is formed covering the surface of the adhesion layer 320. The sealing layer 330 may be silicon nitride (SiN) or silicon carbide (SiC), and the thickness of the sealing layer 330 is between about 200 to 850 angstroms.

In the present invention, the functions of the sealing layer 330 and the adhesion layer 320 are the same as those of the adhesion layer 260 and the sealing layer 270 to improve the reliability of the semiconductor device, since the characteristics of the molecular structures of the sealing layer 330 and the adhesion layer 320 are different. As mentioned above, the adhesion layer 320 is silicon oxynitride (SiON), silicon containing oxygen, nitrogenand hydrogen (SiONH), silicon containing nitrogen and hydrogen (SiNH), silicon containing carbon and nitrogen (SICN) or silicon containing carbon and hydrogen (SiCH). Therefore, the molecular structures of the adhesion layer 320 containing such material have the necessary oxygen, hydrogen or nitrogen elements to combine with copper atoms. For this reason, a firmed structure such as Si—O—Cu forms at the interface between the adhesion layer 320 and the metal layer 310. Therefore, the adhesion between the adhesion layer 320 and the metal layer 310 is improved. In addition, the chemical characteristic of the sealing layer 330 is very stable. While the sealing layer 330 is formed on the adhesion layer 320, it is effective to avoid the copper ions diffusing to other undesired place by providing the sealing layer 330.

According to the method of the present invention, an adhesion layer and a sealing layer are provided to satisfy both the requirements for adhesion between the metal layer and the adhesion layer and that for the metal ions to diffuse from the metal layer to the IMD layer. Therefore, the present invention reduces the electro-migration of copper and the improves adhesion between the sealing layer and the metal layer. Thus, the reliability of the semiconductor device is improved effectively.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method to fabricate an interconnect structure, comprising the following steps:
providing a substrate;
forming an inter-metal dielectric layer on the substrate;
forming a trench on the inter-metal dielectric layer by etching the inter-metal dielectric layer;
forming a barrier layer on the inter-metal dielectric layer and sidewalls and a bottom of the trench;
forming a metal layer on the barrier layer to fill into the trench;
performing a chemical mechanical polishing to planarize a surface of the metal layer;
forming an adhesion layer to cover the surface of the metal layer; and
forming a sealing layer to cover the surface of the metal layer.

2. The method as claimed in claim 1, further comprising the following step:
performing a reduction by providing a reduction gas to remove the metal oxide generated on the metal layer after the chemical mechanical polishing is performed.

3. The method as claimed in claim 2, wherein the adhesion layer is selected from the group consisting of silicon oxynitride (SiON), silicon containing oxygen, nitrogenand hydrogen(SiONH), silicon containing nitrogen and hydrogen (SiNH), silicon containing carbon and nitrogen (SiCN) or silicon containing carbon and hydrogen (SiCH).

4. The method as claimed in claim 3, wherein the thickness of the adhesion layer is between about 200 to 500 angstroms.

5. The method as claimed in claim 4, wherein the sealing layer is selected from the group consisting of silicon nitride (SiN) or silicon carbide (SiC).

6. The method as claimed in claim 5, wherein the thickness of the sealing layer is between about 200 to 850 angstroms.

7. The method as claimed in claim 6, wherein the metal layer is copper.

8. The method as claimed in claim 7, wherein the reduction gas is silane (SiH₄).

9. The method as claimed in claim 7, wherein the reduction gas is selected from the group consisting of ammonia (NH3), hydrogen (H₂), and silane (SiH₄).

10. A method to fabricate an interconnect structure, comprising the following steps:
providing a substrate having a metal line thereon;
forming a first adhesion layer to cover the metal line and the substrate;
forming a first sealing layer to cover the first adhesion layer;
forming an inter-metal dielectric layer on the first sealing layer;
defining the inter-metal dielectric layer by a damascene to form a damascene structure extending through the inter-metal dielectric layer, the first adhesion layer, and the first sealing layer to the metal line;
forming a barrier layer on the inter-metal dielectric layer and sidewalls and a bottom of the damascene structure;
forming a metal layer on the barrier layer to fill into the damascene structure;
performing a chemical mechanical polishing to planarize a surface of the damascene structure;
performing a reduction by providing a reduction gas to remove the metal oxide generated on the metal layer;
forming a second adhesion layer to cover the metal layer and the inter-metal dielectric layer; and
forming a second sealing layer to cover the second sealing layer.

11. The method as claimed in claim 10, wherein the first and second adhesion layer is selected from the group consisting of silicon oxynitride (SiON), silicon containing oxygen, nitrogenand hydrogen (SiONH), silicon containing nitrogen and hydrogen (SiNH), silicon containing carbon and nitrogen (SiCN) or silicon containing carbon and hydrogen (SiCH).

12. The method as claimed in claim 11, wherein the thickness of the first and second adhesion layer is between about 200 to 500 angstroms.

13. The method as claimed in claim 12, wherein the first and second sealing layer is selected from the group consisting of silicon nitride (SiN) or silicon carbide (SiC).

14. The method as claimed in claim 13, wherein the thickness of the first and second sealing layer is between about 200 to 850 angstroms.

15. The method as claimed in claim 14, wherein the metal layer is copper.

16. The method as claimed in claim 15, wherein the reduction gas is silane (SiH₄).

17. The method as claimed in claim 15, wherein the reduction gas is selected from the group consisting of ammonia (NH3), hydrogen (H₂), and silane (SiH₄).
